(19) United States
(12) Patent Application Publication
(10) Pub. No.: US 2023/0421130 A1
(43) Pub. Date: Dec. 28, 2023

(54) ACOUSTIC WAVE DEVICE AND MANUFACTURING METHOD OF THE SAME

(71) Applicant: Murata Manufacturing Co., Ltd., Nagaokakyo-shi (JP)

(72) Inventor: Kazunori INOUE, Nagaokakyo-shi (JP)

(21) Appl. No.: 18/243,711

(22) Filed: Sep. 8, 2023

Related U.S. Application Data
(63) Continuation of application No. PCT/JP2022/015368, filed on Mar. 29, 2022.
(60) Provisional application No. 63/168,307, filed on Mar. 31, 2021.

(51) Int. Cl. H03H 9/13; H03H 9/17; H03H 9/02; H03H 3/02

(52) U.S. Cl. CPC H03H 9/132; H03H 9/173; H03H 9/02118; H03H 3/02; H03H 9/02015; H03H 2003/021

(57) ABSTRACT

An acoustic wave device includes a piezoelectric layer, a support substrate, at least a first and a second functional electrode and a wiring electrode connected to each of the functional electrodes. The wiring electrode includes one or more first wiring electrodes connected to the first and second functional electrodes. A cavity portion is located between the support substrate and the piezoelectric layer. An entirety of the first functional electrode and an entirety of a first wiring electrode connected to the first functional electrode are located on at least one of the first main surface and the second main surface of the piezoelectric layer in an overlapping manner with the cavity portion when viewed from a laminating direction of the support substrate and the piezoelectric layer.

### CROSS REFERENCE TO RELATED APPLICATIONS

This application claims the benefit of priority to Provisional Patent Application No. 63/168,307 filed on Mar. 31, 2021 and is a Continuation application of PCT Application No. PCT/JP2022/015368 filed on Mar. 29, 2022. The entire contents of each application are hereby incorporated herein by reference.

### BACKGROUND OF THE INVENTION

### 1. Field of the Invention

The present invention relates to an acoustic wave device and a manufacturing method of the same.

### 2. Description of the Related Art

Conventionally, acoustic wave devices each of which includes a piezoelectric layer made of lithium niobate or lithium tantalate have been known.

Japanese Unexamined Patent Application Publication No. 2012-257019 discloses an acoustic wave device including a support body formed with a cavity portion, a piezoelectric substrate provided on the support body, the piezoelectric substrate overlapping the cavity portion, and an Interdigital Transducer (IDT) electrode provided on the piezoelectric substrate, the IDT electrode overlapping the cavity portion, wherein a plate wave is excited by the IDT electrode, and an edge portion of the cavity portion does not include a linear portion extending in parallel with a propagation direction of the plate wave excited by the IDT electrode.

### SUMMARY OF THE INVENTION

In the acoustic wave device described in Japanese Unexamined Patent Application Publication No. 2012-257019, electrodes connected to different potentials are disposed adjacent to each other on the same surface of the piezoelectric substrate. In this case, an undesired ripple may occur between the electrodes connected to the different potentials, and as a result, characteristics may be deteriorated.

Preferred embodiments of the present invention provide acoustic wave devices each capable of reducing or preventing deterioration in characteristics due to a ripple. Preferred embodiments of the present invention also provide manufacturing methods of acoustic wave devices capable of reducing or preventing deterioration in characteristics due to a ripple.

An acoustic wave device according to a preferred embodiment of the present invention includes a piezoelectric layer including a first main surface and a second main surface that are opposed to each other, a plurality of electrodes located on at least one main surface of the first main surface and the second main surface of the piezoelectric layer, and a support substrate located on a side of the second main surface of the piezoelectric layer. The plurality of electrodes include at least one pair of functional electrodes and a wiring electrode connected to each of the at least one pair of functional electrodes. The at least one pair of functional electrodes include a first functional electrode connected to a signal wiring line and a second functional electrode paired with the first functional electrode. The wiring electrode includes one or more first wiring electrodes connected to each of the first functional electrode and the second functional electrode. A cavity portion is located between the support substrate and the piezoelectric layer. An entirety of the first functional electrode and an entirety of a first wiring electrode connected to the first functional electrode among the one or more first wiring electrodes are located on at least one of the first main surface and the second main surface of the piezoelectric layer in an overlapping manner with the cavity portion when viewed from a laminating direction of the support substrate and the piezoelectric layer.

A manufacturing method of an acoustic wave device according to a preferred embodiment of the present invention includes preparing an intermediate including a piezoelectric layer including a first main surface and a second main surface that are opposed to each other, a plurality of electrodes located on at least one of the first main surface and the second main surface of the piezoelectric layer, and a support substrate located on a side of the second main surface of the piezoelectric layer, the plurality of electrodes including at least one pair of functional electrodes and a wiring electrode connected to each of the at least one pair of functional electrodes, the at least one pair of functional electrodes including a first functional electrode connected to a signal wiring line and a second functional electrode paired with the first functional electrode, the wiring electrode including one or more first wiring electrodes connected to each of the first functional electrode and the second functional electrode, after the preparing the intermediate, first cover portion joining of disposing a first cover portion at an interval from the first main surface of the piezoelectric layer in an overlapping manner with the first functional electrode, the second functional electrode, and the one or more first wiring electrodes in a view from a laminating direction of the support substrate and the piezoelectric layer, disposing a first support portion between the first cover portion and the piezoelectric layer or the support substrate, and then, joining the first cover portion with the piezoelectric layer or the support substrate, forming a terminal hole penetrating through the first cover portion, forming a terminal electrode in the terminal hole, forming a pad electrode connected to the terminal electrode on or over a main surface of the first cover portion on an opposite side to the piezoelectric layer, forming a cavity portion penetrating through the support substrate, and second cover portion joining of disposing a second cover portion covering the cavity portion on an opposite side to the piezoelectric layer over the support substrate, disposing a second support portion between the second cover portion and the support substrate, and then, joining the second cover portion with the support substrate.

According to preferred embodiments of the present invention, it is possible to provide acoustic wave devices each capable of reducing or preventing deterioration in characteristics due to a ripple. Further, according to preferred embodiments of the present invention, it is possible to provide manufacturing methods of acoustic wave devices each capable of reducing or preventing deterioration in characteristics due to a ripple.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view schematically illustrating an example of an acoustic wave device according to a preferred embodiment of the present invention.

FIG. 2 is a cross-sectional view schematically illustrating an example of an acoustic wave device according to a comparative example.

FIG. 3 is a plan view schematically illustrating an example of an acoustic wave device according to Preferred Embodiment 1 of the present invention.

FIG. 4 is a cross-sectional view of a portion of the acoustic wave device illustrated in FIG. 3, the portion being taken along line A-A.

FIG. 5 is a plan view schematically illustrating an example of an acoustic wave device according to Preferred Embodiment 2 of the present invention.

FIG. 6 is a cross-sectional view of a portion of the acoustic wave device illustrated in FIG. 5, the portion being taken along line B-B.

FIG. 7 is a cross-sectional view schematically illustrating an example of an acoustic wave device according to Preferred Embodiment 3 of the present invention.

FIG. 8 is a cross-sectional view schematically illustrating another example of the acoustic wave device according to Preferred Embodiment 3 of the present invention.

FIG. 9 is a cross-sectional view schematically illustrating an example of a process of producing an intermediate.

FIG. 10 is a cross-sectional view schematically illustrating an example of a process of producing a first cover substrate.

FIG. 11 is a cross-sectional view schematically illustrating an example of a process of joining the intermediate with the first cover substrate.

FIG. 12 is a cross-sectional view schematically illustrating an example of a process of thinning the first cover substrate.

FIG. 13 is a cross-sectional view schematically illustrating an example of a process of forming a terminal hole.

FIG. 14 is a cross-sectional view schematically illustrating an example of a process of forming a seed layer electrode.

FIG. 15 is a cross-sectional view schematically illustrating an example of a process of forming a plating electrode.

FIG. 16 is a cross-sectional view schematically illustrating an example of a process of removing the plating electrode and the seed layer electrode.

FIG. 17 is a cross-sectional view schematically illustrating an example of a process of thinning the support substrate.

FIG. 18 is a cross-sectional view schematically illustrating an example of a process of forming a junction electrode over the support substrate.

FIG. 19 is a cross-sectional view schematically illustrating an example of a process of forming a cavity portion.

FIG. 20 is a cross-sectional view schematically illustrating an example of a process of forming a frequency adjustment film.

FIG. 21 is a cross-sectional view schematically illustrating an example of a process of adjusting a frequency.

FIG. 22 is a cross-sectional view schematically illustrating an example of a process of producing a second cover substrate.

FIG. 23 is a cross-sectional view schematically illustrating an example of a process of joining the intermediate with the second cover substrate.

FIG. 24 is a cross-sectional view schematically illustrating an example of a process of thinning the second cover substrate.

FIG. 25 is a cross-sectional view schematically illustrating an example of a process of forming the seed layer electrode.

FIG. 26 is a cross-sectional view schematically illustrating an example of a process of forming a pad electrode.

FIG. 27 is a cross-sectional view schematically illustrating an example of a singulation process.

FIG. 28 is a schematic perspective view illustrating an external appearance of an example of an acoustic wave device utilizing a bulk wave in a thickness shear mode.

FIG. 29 is a plan view illustrating an electrode structure on a piezoelectric layer of the acoustic wave device illustrated in FIG. 28.

FIG. 30 is a cross-sectional view of a portion taken along line A-A in FIG. 28.

FIG. 31 is a schematic elevational cross-sectional view for describing a Lamb wave propagating through the piezoelectric film of the acoustic wave device.

FIG. 32 is a schematic elevational cross-sectional view for describing a bulk wave in a thickness shear mode propagating through the piezoelectric layer of the acoustic wave device.

FIG. 33 is a diagram illustrating an amplitude direction of a bulk wave in a thickness shear mode.

FIG. 34 is a diagram illustrating an example of resonance characteristics of the acoustic wave device illustrated in FIG. 28.

FIG. 35 is a diagram illustrating a relationship between d/2p, where p is a distance between centers of electrodes adjacent to each other, and d is a thickness of the piezoelectric layer, and a fractional bandwidth of the acoustic wave device as a resonator.

FIG. 36 is a plan view of another example of the acoustic wave device utilizing the bulk wave in the thickness shear mode.

FIG. 37 is a reference diagram illustrating an example of resonance characteristics of the acoustic wave device illustrated in FIG. 28.

FIG. 38 is a diagram illustrating relationships between fractional bandwidths and phase rotation amounts of impedances of spurious emissions normalized by 180 degrees as magnitudes of the spurious emissions when a large number of acoustic wave resonators are configured according to the present preferred embodiment of the present invention.

FIG. 39 is a diagram illustrating relationships among d/2p, metallization ratios MR and fractional bandwidths.

FIG. 40 is a diagram illustrating a map of fractional bandwidths with respect to Euler angles (0°, θ, ψ) of LiNbO₃ when d/p is made as close to 0 as possible.

FIG. 41 is a partially cutout perspective view for describing an example of an acoustic wave device utilizing a Lamb wave.

FIG. 42 is a cross-sectional view schematically illustrating an example of an acoustic wave device utilizing a bulk wave.

### DETAILED DESCRIPTION OF THE PREFERRED EMBODIMENTS

Acoustic wave devices according to preferred embodiments of the present invention will be described below.

An acoustic wave device according to a preferred embodiment of the present invention includes a piezoelectric layer and a plurality of electrodes provided on at least one main surface of the piezoelectric layer.

In each of first, second, and third aspects of preferred embodiments of the present invention, an acoustic wave device includes a piezoelectric layer made of lithium niobate or lithium tantalate, and a first electrode and a second electrode that face each other in a direction intersecting a thickness direction of the piezoelectric layer.

In the first aspect, a bulk wave in a thickness shear mode such as a thickness shear primary mode is utilized. Additionally, in the second aspect, the first electrode and the second electrode are electrodes adjacent to each other, and d/p is equal to or less than about 0.5, for example, where d is a thickness of the piezoelectric layer and p is a distance between centers of the first electrode and the second electrode. Thus, in each of the first and second aspects, a Q value can be increased even when miniaturization is attained.

In the third aspect, a Lamb wave is utilized as a plate wave. Then, resonance characteristics using the Lamb wave can be obtained.

According to a fourth aspect of the present invention, an acoustic wave device includes a piezoelectric layer made of lithium niobate or lithium tantalate, and an upper electrode and a lower electrode opposed to each other in a thickness direction of the piezoelectric layer with the piezoelectric layer interposed therebetween. In the fourth aspect, a bulk wave is utilized.

Hereinafter, specific preferred embodiments of the present invention will be described with reference to the drawings to clarify the present invention.

The drawings, which will be illustrated below, are schematic, and the dimensions, the aspect ratio scale sizes, and the like may be different from those of an actual product.

It should be noted that each preferred embodiment described in the present specification is merely an example, and partial replacement or combination of configurations is possible among different preferred embodiments. In addition, when the preferred embodiments are not particularly distinguished from each other, acoustic wave devices thereof are simply referred to as an “acoustic wave device according to a preferred embodiment of the present invention”.

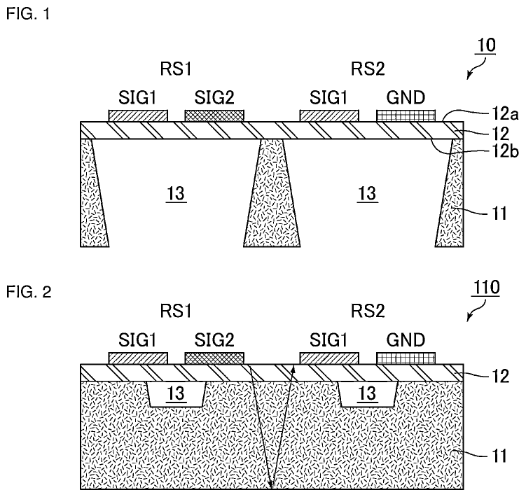

FIG. 1 is a cross-sectional view schematically illustrating an example of an acoustic wave device according to a preferred embodiment of the present invention.

An acoustic wave device 10 illustrated in FIG. 1 includes a support substrate 11 and a piezoelectric layer 12 provided on one main surface of the support substrate 11. The piezoelectric layer 12 includes a first main surface 12a and a second main surface 12b that are opposed to each other. The support substrate 11 includes a cavity portion 13 in a main surface on the second main surface 12b side of the piezoelectric layer 12. The piezoelectric layer 12 is provided on the main surface of the support substrate 11 so as to cover the cavity portion 13.

The acoustic wave device 10 illustrated in FIG. 1 further includes an electrode SIG1, an electrode SIG2, and an electrode GND. The electrode SIG1, the electrode SIG2, and the electrode GND are all provided on the first main surface 12a of the piezoelectric layer 12. Among these, the electrode SIG1 and the electrode SIG2 are connected to signal wiring lines (not illustrated). The electrode GND is connected to a ground potential (not illustrated). The electrode SIG1 and the electrode SIG2 that are connected to the signal wiring lines are electrodes having mutually different potentials.

The electrode SIG1 and the electrode SIG2 that are positioned on the left side in FIG. 1 define a first resonator RS1, and the electrode SIG1 and the GND electrode positioned on the right side define a second resonator RS2.

In the acoustic wave device 10 illustrated in FIG. 1, the electrode SIG1 and the electrode SIG2 that are connected to the signal wiring lines are provided so as to entirely overlap the cavity portion 13 when viewed from a laminating direction of the support substrate 11 and the piezoelectric layer 12 (a vertical direction in FIG. 1). In other words, when viewed from the laminating direction of the support substrate 11 and the piezoelectric layer 12, the electrode SIG1 and the electrode SIG2 that are connected to the signal wiring lines are not provided at a portion of the piezoelectric layer 12 that does not overlap the cavity portion 13.

FIG. 2 is a cross-sectional view schematically illustrating an example of an acoustic wave device according to a comparative example.

In an acoustic wave device 110 illustrated in FIG. 2, when viewed from the laminating direction of the support substrate 11 and the piezoelectric layer 12, the electrode SIG1 and the electrode SIG2 that are connected to the signal wiring lines are provided so as to overlap not only the cavity portion 13 but also the support substrate 11. In this case, between the electrode SIG1 and the electrode SIG2 that are connected to mutually different potentials, a wave leaking as indicated by arrows in FIG. 2 is reflected by the support substrate 11 and picked up, so that an undesired ripple is generated, and as a result, deterioration in characteristics may occur.

On the other hand, in the acoustic wave device 10 illustrated in FIG. 1, when viewed from the laminating direction of the support substrate 11 and the piezoelectric layer 12, the electrode SIG1 and the electrode SIG2 that are connected to the signal wiring lines are provided so as to entirely overlap the cavity portion 13, and thus, a leakage wave is less likely to be picked up, which can reduce or prevent deterioration in characteristics due to a ripple.

In FIG. 1, when viewed from the laminating direction of the support substrate 11 and the piezoelectric layer 12, both of the electrode SIG1 and the electrode SIG2 that are connected to the signal wiring lines are provided so as to entirely overlap the cavity portion 13, but at least one of the electrode SIG1 and the electrode SIG2 that are connected to the signal wiring lines may entirely overlap the cavity portion 13.

Additionally, in FIG. 1, when viewed from the laminating direction of the support substrate 11 and the piezoelectric layer 12, the electrode GND connected to the ground potential is also provided so as to entirely overlap the cavity portion 13, but the electrode GND connected to the ground potential does not need to be provided so as to entirely overlap the cavity portion 13.

Hereinafter, preferred embodiments in which an acoustic wave device according to a preferred embodiment of the present invention is more specifically disclosed will be described.

However, the present invention is not limited to these preferred embodiments.

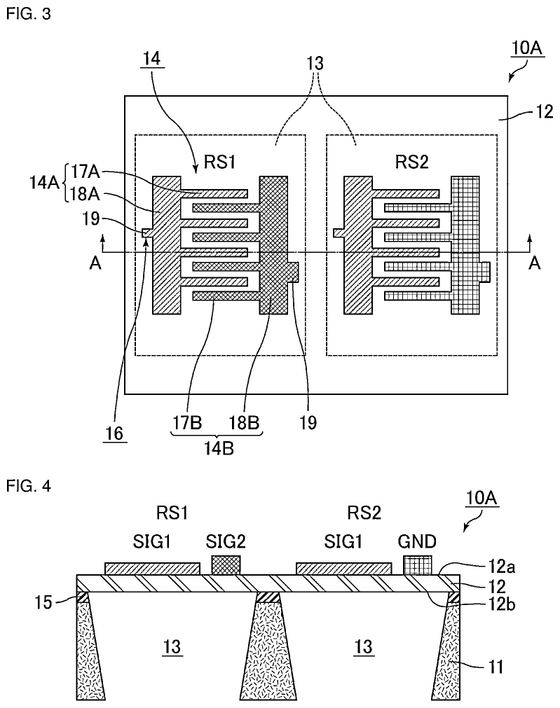

FIG. 3 is a plan view schematically illustrating an example of an acoustic wave device according to Preferred Embodiment 1. FIG. 4 is a cross-sectional view of a portion of the acoustic wave device illustrated in FIG. 3, the portion being taken along line A-A.

An acoustic wave device 10A according to Preferred Embodiment 1 illustrated in FIG. 3 and FIG. 4 includes the support substrate 11, an intermediate layer 15 laminated on the support substrate 11, the piezoelectric layer 12 laminated on the intermediate layer 15, and a plurality of electrodes (functional electrodes 14, and the like) provided on the piezoelectric layer 12.

The cavity portion 13 (hereinafter, also referred to as a first cavity portion 13) is provided so as to penetrate through the support substrate 11 and the intermediate layer 15 in the laminating direction (a vertical direction in FIG. 4) of the support substrate 11 and the piezoelectric layer 12. Note that the intermediate layer 15 does not need to be provided. In addition, the cavity portion 13 may be provided inside the intermediate layer 15 or the support substrate 11 without penetrating through the support substrate 11 and the intermediate layer 15. That is, the cavity portion 13 may be provided between the support substrate 11 and the piezoelectric layer 12.

The support substrate 11 is made of, for example, silicon (Si). The material of the support substrate 11 is not limited to the material described above, and examples of the material include piezoelectric materials such as aluminum oxide, lithium tantalate, lithium niobate, and quartz crystal; various ceramics such as alumina, sapphire, silicon nitride, aluminum nitride, silicon carbide, zirconia, cordierite, mullite, steatite, and forsterite; dielectrics such as diamond and glass; semiconductors such as gallium nitride; and resin.

The intermediate layer 15 is made of, for example, silicon oxide (SiOₓ). In that case, the intermediate layer 15 may be made of SiO₂. The material of the intermediate layer 15 is not limited to the material described above, and examples thereof include silicon nitride (SiₓN_{y}). In that case, the intermediate layer 15 may be made of Si₃N₄.

The piezoelectric layer 12 is made of, for example, lithium niobate (LiNbOₓ) or lithium tantalate (LiTaOₓ). In that case, the piezoelectric layer 12 may be made of LiNbO₃ or LiTaO₃.

The plurality of electrodes include at least one pair of functional electrodes 14 and a wiring electrode 16 connected to each of the functional electrodes 14.

The functional electrodes 14 include a first functional electrode 14A connected to a signal wiring line (not illustrated) and a second functional electrode 14B paired with the first functional electrode 14A. The wiring electrode 16 includes one or more first wiring electrodes 19 connected to the respective first functional electrode 14A and second functional electrode 14B.

As illustrated in FIG. 3, the functional electrodes 14 include, for example, first electrodes 17A (hereinafter, also referred to as first electrode fingers 17A) and second electrodes 17B (hereinafter, also referred to as second electrode fingers 17B) that face each other, a first busbar electrode 18A to which the first electrodes 17A are connected, and a second busbar electrode 18B to which the second electrodes 17B are connected. The first electrodes 17A and the first busbar electrode 18A define a first comb-shaped electrode (first IDT electrode) that is the first functional electrode 14A, and the second electrodes 17B and the second busbar electrode 18B define a second comb-shaped electrode (second IDT electrode) that is the second functional electrode 14B.

FIG. 3 and FIG. 4 illustrate two functional electrodes 14 and the plurality of wiring electrodes 16 connected to the two functional electrodes 14. As illustrated in FIG. 3 and FIG. 4, the functional electrodes 14 and the wiring electrodes 16 include both the electrode SIG1 and the electrode SIG2 that are connected to the signal wiring lines (not illustrated) and the electrode GND connected to a ground potential (not illustrated).

The electrode SIG1, the electrode SIG2, and the electrode GND are all provided on the first main surface 12a of the piezoelectric layer 12. The electrode SIG1 and the electrode SIG2 that are connected to the signal wiring lines are electrodes having mutually different potentials.

In FIG. 3 and FIG. 4, the electrode SIG1 and the electrode SIG2 that are positioned on the left side define the first resonator RS1, and the electrode SIG1 and the electrode GND that are positioned on the right side define the second resonator RS2.

In the acoustic wave device 10A illustrated in FIG. 3 and FIG. 4, the entirety of the first functional electrode 14A (that is, the first comb-shaped electrode of the first resonator RS1 and the first comb-shaped electrode of the second resonator RS2) connected to the signal wiring line and the entirety of the first wiring electrode 19 connected to the first functional electrode 14A (that is, the first wiring electrode 19 connected to the first comb-shaped electrode of the first resonator RS1 and the first wiring electrode 19 connected to the first comb-shaped electrode of the second resonator RS2) are provided so as to overlap the cavity portion 13 when viewed from the laminating direction of the support substrate 11 and the piezoelectric layer 12. In other words, the electrode SIG1 connected to the signal wiring line is not provided on a portion of the piezoelectric layer 12 that does not overlap the cavity portion 13 when viewed from the laminating direction of the support substrate 11 and the piezoelectric layer 12. This makes it difficult for a leaked unnecessary wave to be picked up, thus making it possible to reduce or prevent deterioration in characteristics.

Furthermore, when viewed in the laminating direction of the support substrate 11 and the piezoelectric layer 12, the entirety of the second functional electrode 14B connected to the signal wiring line (that is, the second comb-shaped electrode of the first resonator RS1) and the entirety of the first wiring electrode 19 connected to the second functional electrode 14B (that is, the first wiring electrode 19 connected to the second comb-shaped electrode of the first resonator RS1) preferably overlap the cavity portion 13. In other words, among the electrodes paired with the electrodes SIG1, the electrode SIG2 connected to the signal wiring line is preferably not provided on a portion of the piezoelectric layer 12 that does not overlap the cavity portion 13 when viewed from the laminating direction of the support substrate 11 and the piezoelectric layer 12.

In FIG. 3 and FIG. 4, when viewed from the laminating direction of the support substrate 11 and the piezoelectric layer 12, the entirety of the second functional electrode 14B connected to the signal potential (that is, the second comb-shaped electrode of the second resonator RS2) and the entirety of the first wiring electrode 19 connected to the second functional electrode 14B (that is, the first wiring electrode 19 connected to the second comb-shaped electrode of the second resonator RS2) are also provided so as to overlap the cavity portion 13, but the entirety of the electrode GND connected to the ground potential does not need to be provided so as to overlap the cavity portion 13.

The functional electrode 14 is made of an appropriate metal or alloy such as Al or an AlCu alloy. For example, the functional electrode 14 has a structure in which an Al layer is laminated on a Ti layer. Note that an adhesion layer other than the Ti layer may be used.

The wiring electrode 16 is made of an appropriate metal or alloy such as Al or an AlCu alloy. For example, the wiring electrode 16 has a structure in which an Al layer is laminated on a Ti layer. Note that an adhesion layer other than the Ti layer may be used.

The acoustic wave device 10A according to Preferred Embodiment 1 may be included in an acoustic wave device package as in Preferred Embodiment 2.

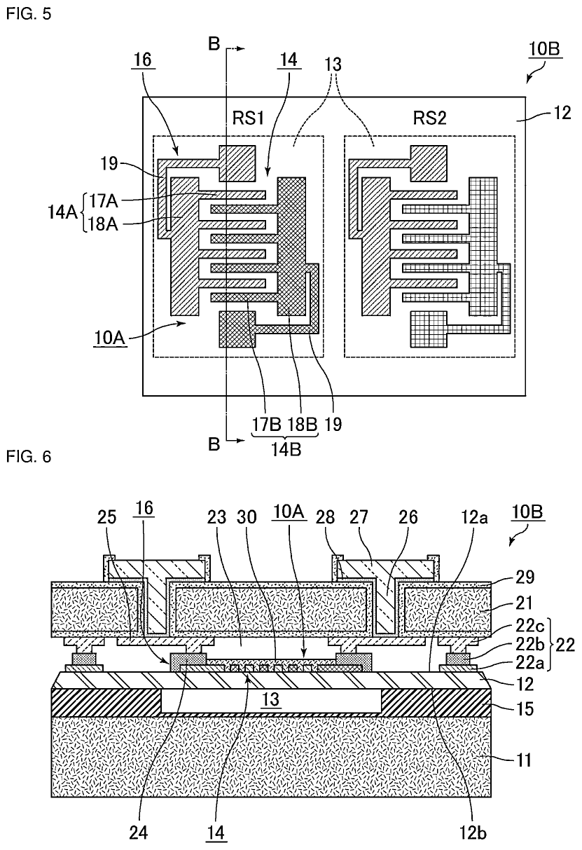

FIG. 5 is a plan view schematically illustrating an example of an acoustic wave device according to Preferred Embodiment 2. FIG. 6 is a cross-sectional view of a portion of the acoustic wave device illustrated in FIG. 5, the portion being taken along line B-B.

An acoustic wave device 10B according to Preferred Embodiment 2 illustrated in FIG. 5 and FIG. 6 includes, in addition to the acoustic wave device 10A according to Preferred Embodiment 1, a first cover portion 21 that covers the functional electrode 14 and the wiring electrode 16 thereof, and a first support portion 22 provided between the first cover portion 21 and the support substrate 11 or the piezoelectric layer 12.

The first cover portion 21 is provided at an interval from the first main surface 12a of the piezoelectric layer 12 so as to overlap the functional electrode 14 and the wiring electrode 16 thereof when viewed in the laminating direction of the support substrate 11 and the piezoelectric layer 12. As a result, a second cavity portion 23 is provided between the first cover portion 21 and the functional electrode 14 on the support substrate 11.

The first cover portion 21 is made of, for example, Si. The material of the first cover portion 21 may be the same as or different from the material of the support substrate 11.

The first support portion 22 is defined by, for example, a ring electrode surrounding the functional electrode 14 and the wiring electrode 16 thereof. In this case, the first support portion 22 includes, for example, a multilayer body of a conductive film 22a, a seal electrode 22b laminated on the conductive film 22a, and a junction electrode 22c laminated on the seal electrode 22b, from the support substrate 11 side. The first cover portion 21 and the piezoelectric layer 12 are joined to each other with the ring electrode interposed therebetween. The first support portion 22 does not need to include the conductive film 22a, and may include a multilayer body of the seal electrode 22b and the junction electrode 22c laminated on the seal electrode 22b, from the support substrate 11 side.

The conductive film 22a is made of, for example, the same material as that of the functional electrode 14. The seal electrode 22b includes, for example, gold (Au). The junction electrode 22c includes, for example, Au.

A second wiring electrode 24 connected to the first wiring electrode 19 is provided on the first wiring electrode 19.

Further, a third wiring electrode 25 connected to the second wiring electrode 24 is provided on a main surface of the first cover portion 21 on the piezoelectric layer 12 side.

As illustrated in FIG. 6, the acoustic wave device 10B preferably further includes a terminal electrode 26 penetrating through the first cover portion 21 and electrically connected to the third wiring electrode 25, and a pad electrode 27 connected to the terminal electrode 26. A seed layer electrode 28 may be provided on bottom surfaces of the terminal electrode 26 and the pad electrode 27.

The terminal electrode 26 includes, for example, a Cu layer such as a Cu plating layer. The pad electrode 27 includes, for example, a Cu layer such as a Cu plating layer, an Ni layer such as an Ni plating layer, and an Au layer such as an Au plating layer in this order from the terminal electrode 26 side. The seed layer electrode 28 includes, for example, a Ti layer and a Cu layer from the first cover portion 21 side.

The terminal electrode 26 and the pad electrode 27 define an under bump metal (UBM) layer. The UBM layer is connected to the third wiring electrode 25. A bump such as a ball grid array (BGA) may be provided on the pad electrode 27 to define the UBM layer.

The main surface of the first cover portion 21 on the piezoelectric layer 12 side and a main surface of the first cover portion 21 on the side opposite to the piezoelectric layer 12 may be covered with an insulating film 29.

The insulating film 29 is made of, for example, SiOₓ or the like. In this case, the insulating film 29 may be made of SiO₂.

The surface of a functional electrode may be covered with a protective film 30.

The protective film 30 is made of, for example, SiCₓ, SiₓN_{y}, or the like, or is defined by a multilayer body of these materials. In this case, the protective film 30 may be made of SiO₂, Si₃N₄, or the like, or may be defined by a multilayer body of these materials.

Alternatively, the acoustic wave device 10A according to Preferred Embodiment 1 may be used for forming an acoustic wave device package as in Preferred Embodiment 3.

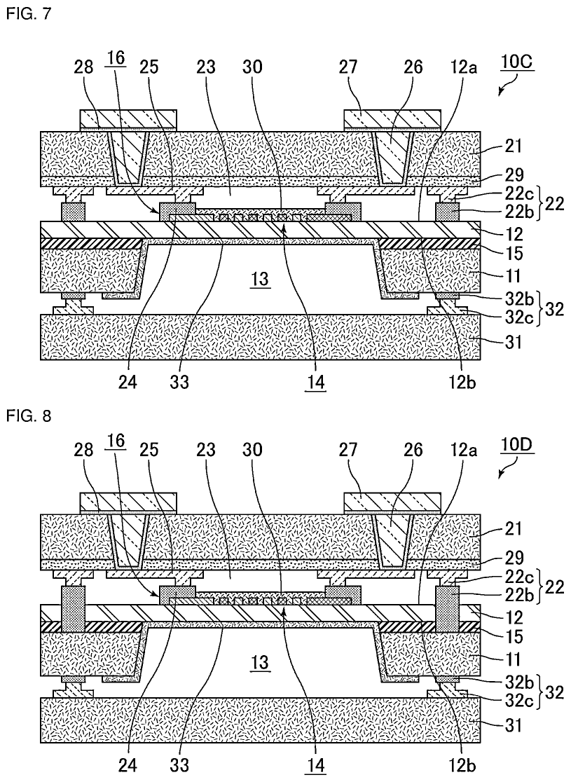

FIG. 7 is a cross-sectional view schematically illustrating an example of an acoustic wave device according to Preferred Embodiment 3.

An acoustic wave device 10C according to Preferred Embodiment 3 illustrated in FIG. 7 includes, in addition to the acoustic wave device 10A according to Preferred Embodiment 1, the first cover portion 21 that covers the functional electrode 14 and the wiring electrode 16 thereof, the first support portion 22 provided between the first cover portion 21 and the support substrate 11 or the piezoelectric layer 12, a second cover portion 31 that closes the first cavity portion 13, and a second support portion 32 provided between the second cover portion 31 and the support substrate 11.

The acoustic wave device 10C according to Preferred Embodiment 3 differs from the acoustic wave device 10B according to Preferred Embodiment 2 in that (1) the first cavity portion 13 is provided so as to penetrate through the support substrate 11 and the intermediate layer 15, and (2) the second cover portion 31 is provided on the first cavity portion 13 side so as to close the first cavity portion 13.

The second cover portion 31 is provided on the side opposite to the piezoelectric layer 12 over the support substrate 11.

The second cover portion 31 is made of, for example, Si. The material of the second cover portion 31 may be the same as or different from the material of the support substrate 11. Furthermore, the material of the second cover portion 31 may be the same as or different from the material of the first cover portion 21.

The second support portion 32 is defined by, for example, a ring electrode surrounding the first cavity portion 13. In this case, the second support portion 32 includes, for example, a multilayer body of a seal electrode 32b and a junction electrode 32c laminated on the seal electrode 32b from the support substrate 11 side. The second cover portion 31 and the support substrate 11 are joined to each other with the ring electrode interposed therebetween.

A frequency adjustment film 33 may be provided on a surface of the piezoelectric layer 12 on the second cover portion 31 side so as to overlap the first cavity portion 13.

The frequency adjustment film 33 is made of, for example, SiOₓ, SiₓN_{y}, or the like, or is defined by a multilayer body of these materials. In this case, the frequency adjustment film 33 may be made of SiO₂, Si₃N₄, or the like, or may be defined by a multilayer body of these materials.

FIG. 8 is a cross-sectional view schematically illustrating another example of the acoustic wave device according to Preferred Embodiment 3.

As in an acoustic wave device 10D illustrated in FIG. 8, the first support portion 22 (for example, a ring electrode) provided between the first cover portion 21 and the support substrate 11 may penetrate through the piezoelectric layer 12 and the intermediate layer 15 and be in contact with the support substrate 11. In this case, when viewed from a laminating direction of the support substrate 11 and the piezoelectric layer 12, no electrode provided on the piezoelectric layer 12 that does not overlap the first cavity portion 13 exists. Thus, adhesiveness is further improved.

The acoustic wave device according to Preferred Embodiment 3 can be manufactured by, for example, the following method. A preferred embodiment of the present invention also includes such a manufacturing method of an acoustic wave device.

### (1) Preparing Intermediate

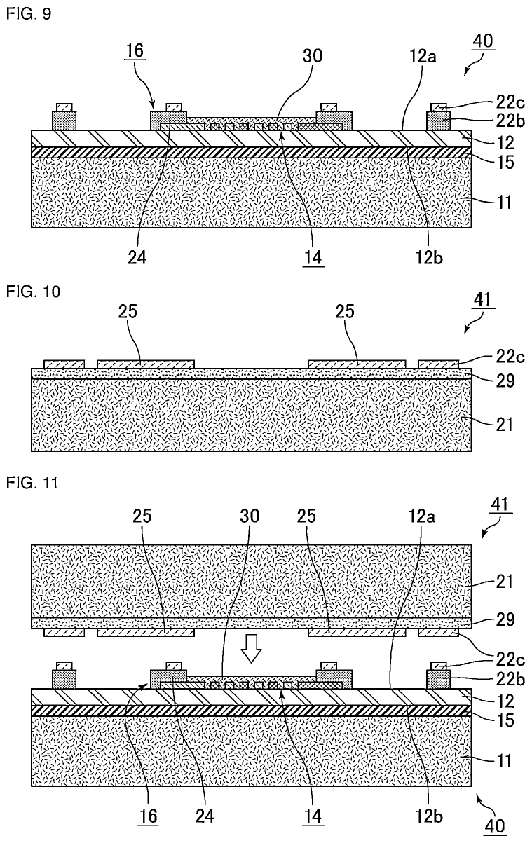

FIG. 9 is a cross-sectional view schematically illustrating an example of a process of producing an intermediate.

The functional electrode 14 and the wiring electrode 16 thereof, the seal electrode 22b, the junction electrode 22c, and the protective film 30 are formed on or over a surface of a junction substrate including the thin piezoelectric layer 12, the intermediate layer 15 (also referred to as a junction layer), and the support substrate 11 such as a Si substrate by using an existing method (such as a lift-off method). The junction electrode 22c includes, for example, a Ti layer and an Au layer from the support substrate 11 side. Thus, an intermediate 40 is produced.

### (2) Producing First Cover Substrate

FIG. 10 is a cross-sectional view schematically illustrating an example of a process of producing a first cover substrate.

The junction electrode 22c, the third wiring electrode 25, and the insulating film 29 are formed on or over the surface of the first cover portion 21 such as a Si substrate by using an existing method (such as a lift-off method). The junction electrode 22c includes, for example, a Ti layer and an Au layer from the first cover portion 21 side. Similarly, the third wiring electrode 25 includes, for example, a Ti layer and an Au layer from the first cover portion 21 side. Thus, a first cover substrate 41 is produced.

(3) Joining Intermediate with First Cover Substrate

FIG. 11 is a cross-sectional view schematically illustrating an example of a process of joining an intermediate with a first cover substrate.

The intermediate 40 and the first cover substrate 41 are bonded to each other by Au—Au joining.

### (4) Thinning First Cover Substrate

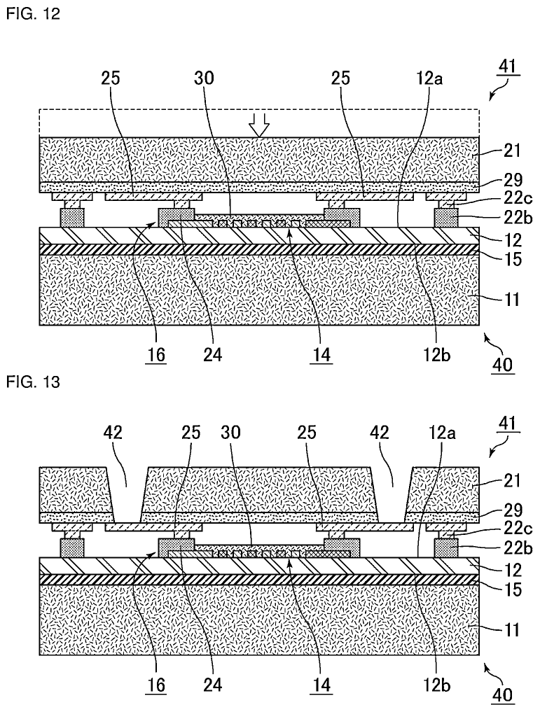

FIG. 12 is a cross-sectional view schematically illustrating an example of a process of thinning the first cover substrate.

A back surface of the first cover portion 21 of the first cover substrate 41 bonded to the intermediate 40 is thinned by grinding by using an existing method.

### (5) Forming Terminal Hole

FIG. 13 is a cross-sectional view schematically illustrating an example of a process of forming a terminal hole.

A terminal hole 42 is formed by removing the first cover portion 21 and the insulating film 29 of the first cover substrate 41 by using an existing method (such as a Through Silicon Via (TSV) process).

### (6) Forming Seed Layer Electrode

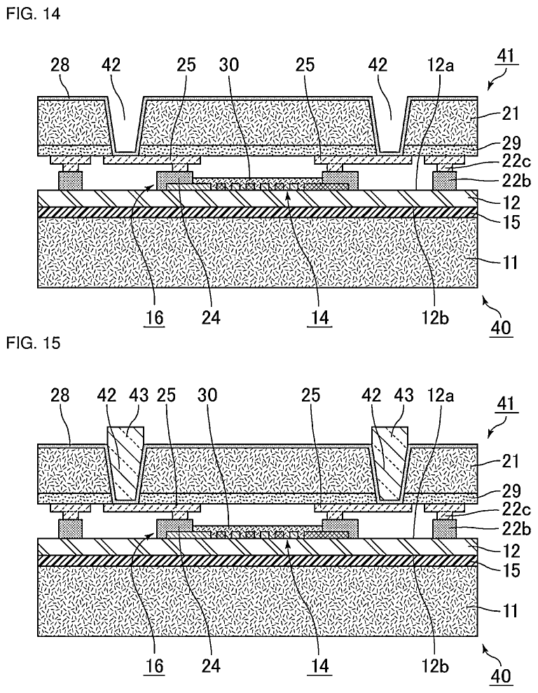

FIG. 14 is a cross-sectional view schematically illustrating an example of a process of forming a seed layer electrode.

The seed layer electrode 28 is formed on a surface of the first cover substrate 41 by film formation by using an existing method. The seed layer electrode 28 includes, for example, a Ti layer and a Cu layer from the first cover portion 21 side.

### (7) Forming Plating Electrode

FIG. 15 is a cross-sectional view schematically illustrating an example of a process of forming a plating electrode.

After a pattern of a plating resist (not illustrated) is formed by using an existing method, Cu plating is performed to form a plating electrode 43 on a surface of the seed layer electrode 28. Thus, the terminal hole 42 is filled with the plating electrode 43, and the plating electrode 43 is formed on or over the surface of the first cover portion 21. Thereafter, the plating resist is removed.

### (8) Removing Plating Electrode and Seed Layer Electrode

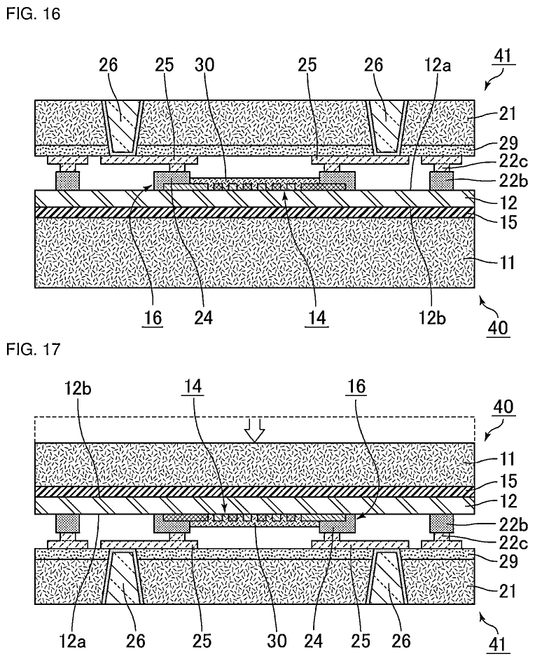

FIG. 16 is a cross-sectional view schematically illustrating an example of a process of removing a plating electrode and a seed layer electrode.

The plating electrode 43 and the seed layer electrode 28 that are formed on or over the surface of the first cover portion 21 are removed by using an existing method. Thus, the terminal electrode 26 is exposed.

### (9) Thinning Support Substrate

FIG. 17 is a cross-sectional view schematically illustrating an example of a process of thinning a support substrate.

The back surface of the support substrate 11 of the intermediate 40 bonded to the first cover substrate 41 is thinned by grinding by using an existing method.

### (10) Forming Junction Electrode Over Support Substrate

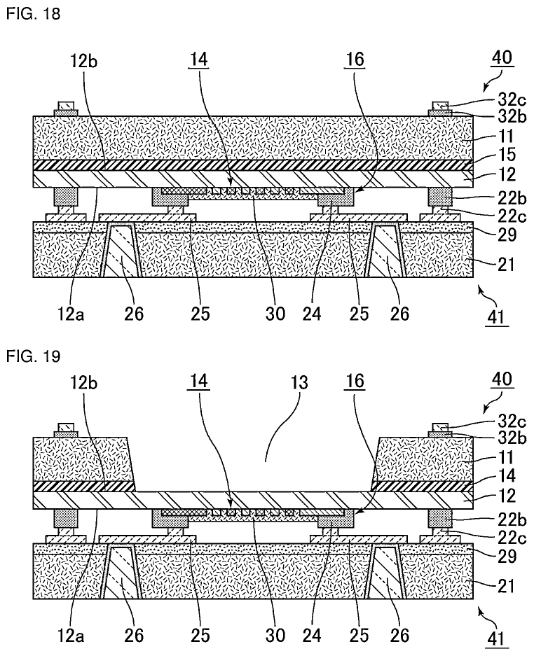

FIG. 18 is a cross-sectional view schematically illustrating an example of a process of forming a junction electrode over the support substrate.

The seal electrode 32b and the junction electrode 32c are formed on or over the surface on the back surface side of the support substrate 11 by an existing method (such as a lift-off method). The junction electrode 32c include, for example, a Ti layer and an Au layer from the support substrate 11 side.

### (11) Forming Cavity Portion

FIG. 19 is a cross-sectional view schematically illustrating an example of a process of forming a cavity portion.

The back surface of the support substrate 11 and the intermediate layer 15 that define the intermediate 40 are etched by using an existing method (such as s Through Silicon Via (TSV) process) to form the cavity portion (first cavity portion) 13 penetrating through the support substrate 11 and the intermediate layer 15.

### (12) Forming Frequency Adjustment Film

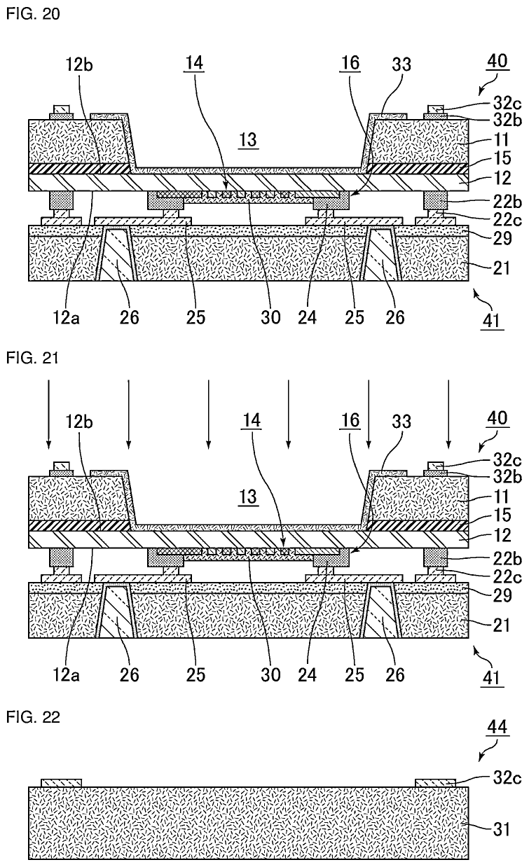

FIG. 20 is a cross-sectional view schematically illustrating an example of a process of forming a frequency adjustment film.

The frequency adjustment film 33 is formed on the surface on the back surface side of the piezoelectric layer 12 so as to overlap the first cavity portion 13 by using an existing method (such as film formation, or patterning).

### (13) Adjusting Frequency

FIG. 21 is a cross-sectional view schematically illustrating an example of a process of adjusting a frequency.

Frequency characteristics are checked by probing, on a side on which the terminal electrode 26 is present, a substrate obtained by bonding the intermediate 40 and the first cover substrate 41. Thereafter, the frequency adjustment film 33 is etched to a desired thickness by using an existing method (such as ion etching) to adjust the frequency. This process is repeated until a desired frequency can be obtained.

### (14) Producing Second Cover Substrate

FIG. 22 is a cross-sectional view schematically illustrating an example of a process of producing a second cover substrate.

The junction electrode 32c is formed on a surface of the second cover portion 31 such as a Si substrate by using an existing method (such as a lift-off method). The junction electrode 32c includes, for example, a Ti layer and an Au layer from the second cover portion 31 side. Thus, the second cover substrate 44 is produced.

### (15) Joining Intermediate and Second Cover Substrate

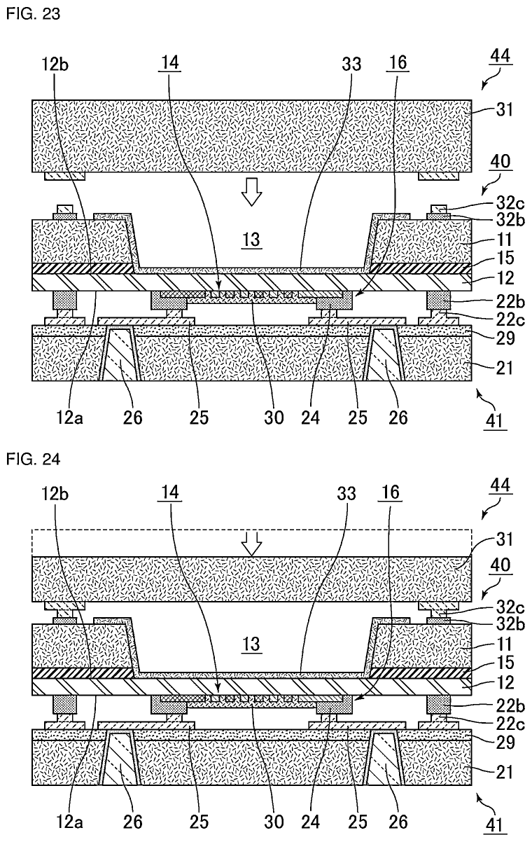

FIG. 23 is a cross-sectional view schematically illustrating an example of a process of joining an intermediate with a second cover substrate.

The intermediate 40 bonded to the first cover substrate 41 and the second cover substrate 44 are bonded by Au—Au joining.

### (16) Thinning Second Cover Substrate

FIG. 24 is a cross-sectional view schematically illustrating an example of a process of thinning the second cover substrate.

A back surface of the second cover portion 31 of the second cover substrate 44 bonded to the intermediate 40 is thinned by grinding by using an existing method.

### (17) Forming Seed Layer Electrode

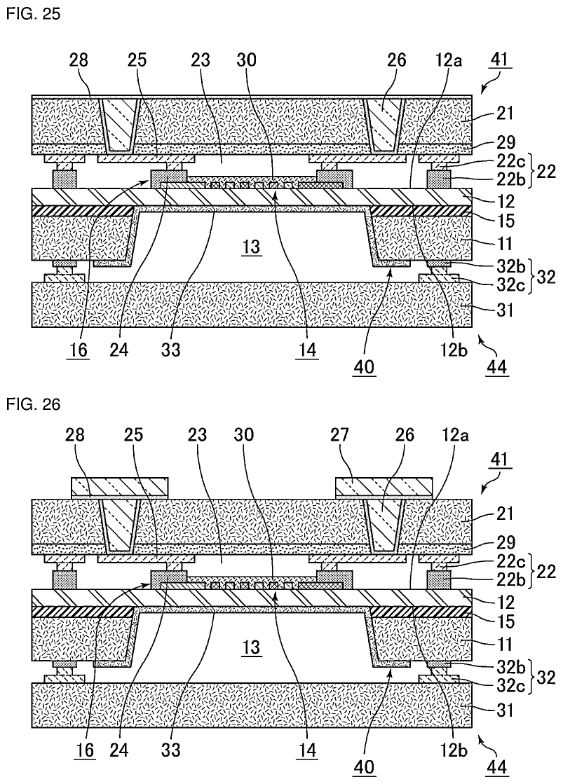

FIG. 25 is a cross-sectional view schematically illustrating an example of a process of forming a seed layer electrode.

The seed layer electrode 28 is formed by film formation on the surface of the first cover substrate 41 on the terminal electrode 26 side by using an existing method. The seed layer electrode 28 includes, for example, a Ti layer and a Cu layer from the first cover portion 21 side.

### (18) Forming Pad Electrode

FIG. 26 is a cross-sectional view schematically illustrating an example of a process of forming a pad electrode.

By using an existing method, a pattern of a plating resist (not illustrated) is formed, Cu plating, Ni plating, and Au plating are performed from the first cover portion 21 side, and then, the plating resist and the seed layer electrode 28 are removed. Thus, the pad electrode 27 is formed on or over the surface of the terminal electrode 26.

### (19) Singulation

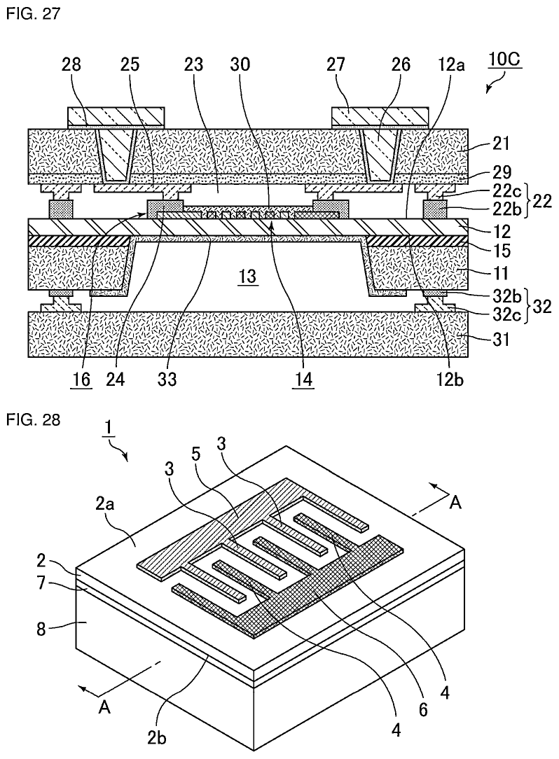

FIG. 27 is a cross-sectional view schematically illustrating an example of a singulation process. Note that the singulation process is not essential.

When the intermediate is divided into a plurality of singulation regions, singulation is performed by cutting the piezoelectric layer 12, the support substrate 11, the first cover portion 21, and the second cover portion 31 along boundary lines of the singulation regions by using an existing method (such as a cutting method with a dicing machine). When the intermediate is not divided into the plurality of singulation regions, the singulation process is unnecessary.

Through the above processes, the acoustic wave device 10C can be obtained.

Hereinafter, a thickness shear mode and a plate wave will be described in detail. Hereinafter, an example in which the functional electrode is an IDT electrode will be described. A support in the following example corresponds to the support substrate according to a preferred embodiment of the present invention, and an insulating layer corresponds to the intermediate layer.

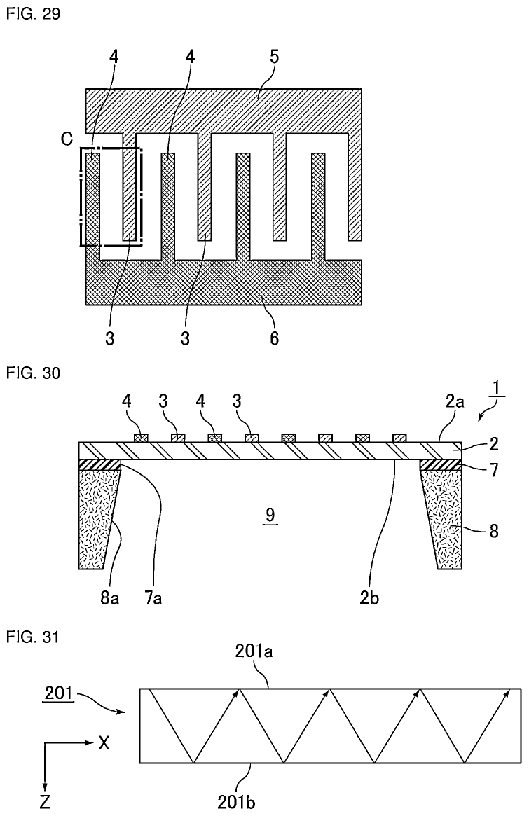

FIG. 28 is a schematic perspective view illustrating an external appearance of an example of an acoustic wave device utilizing a bulk wave in a thickness shear mode. FIG. 29 is a plan view illustrating an electrode structure on a piezoelectric layer of the acoustic wave device illustrated in FIG. 28. FIG. 30 is a cross-sectional view of a portion taken along line A-A in FIG. 28.

An acoustic wave device 1 includes a piezoelectric layer 2 made of, for example, LiNbO₃. The piezoelectric layer 2 may be made of LiTaO₃. Cut angles of LiNbO₃ or LiTaO₃ are, for example, Z-cut, but may also be rotated Y-cut or X-cut. Preferably, Y-propagation and X-propagation whose propagation directions are ±30° are preferred. A thickness of the piezoelectric layer 2 is not particularly limited, but is preferably equal to or more than about 50 nm and equal to or less than about 1000 nm, for example, in order to effectively excite the thickness shear mode. The piezoelectric layer 2 includes a first main surface 2a and a second main surface 2b that are opposed to each other. Electrodes 3 and 4 are provided on the first main surface 2a of the piezoelectric layer 2. Here, the electrode 3 is an example of a “first electrode”, and the electrode 4 is an example of a “second electrode”. In FIG. 28 and FIG. 29, a plurality of electrodes 3 are a plurality of first electrode fingers connected to a first busbar electrode 5. A plurality of electrodes 4 are a plurality of second electrode fingers connected to a second busbar electrode 6. The plurality of electrodes 3 and the plurality of electrodes 4 are interdigitated with each other. Each of the electrode 3 and the electrode 4 has a rectangular shape and has a longitudinal direction. The electrode 3 and the electrode 4 adjacent thereto face each other in a direction orthogonal to the longitudinal direction. The plurality of electrodes 3, the plurality of electrodes 4, the first busbar electrode 5, and the second busbar electrode 6 define an Interdigital Transducer (IDT) electrode. Both the longitudinal direction of the electrodes 3 and 4 and a direction orthogonal to the longitudinal direction of the electrodes 3 and 4 are directions intersecting a thickness direction of the piezoelectric layer 2. Thus, it can also be said that the electrode 3 and the electrode 4 adjacent thereto face each other in a direction intersecting the thickness direction of the piezoelectric layer 2. Further, the longitudinal direction of the electrodes 3 and 4 may be replaced with the direction orthogonal to the longitudinal direction of the electrodes 3 and 4 illustrated in FIG. 28 and FIG. 29. That is, in FIG. 28 and FIG. 29, the electrodes 3 and 4 may extend in the direction in which the first busbar electrode 5 and the second busbar electrode 6 extend. In this case, the first busbar electrode 5 and the second busbar electrode 6 extend in the direction in which the electrodes 3 and 4 extend in FIG. 28 and FIG. 29. Then, a plurality of pairs of structures in which the electrode 3 connected to one potential and the electrode 4 connected to the other potential are adjacent to each other are provided in the direction orthogonal to the longitudinal direction of the electrodes 3 and 4. Here, the fact that the electrode 3 and the electrode 4 are adjacent to each other refers not to a case where the electrode 3 and the electrode 4 are disposed so as to be in direct contact with each other but to a case where the electrode 3 and the electrode 4 are disposed with an interval therebetween. When an electrode 3 and an electrode 4 are adjacent to each other, no electrode connected to a hot electrode or a ground electrode is disposed between the electrode 3 and the electrode 4, as well as other electrodes 3 and 4 are not disposed. The number of pairs does not need to be an integer number, but may be 1.5, 2.5, or the like. A distance between centers of the electrodes 3 and 4, that is, a pitch is preferably within a range being equal to or more than about 1 μm and equal to or less than about 10 μm, for example. Note that the distance between the centers of the electrodes 3 and 4 is a distance connecting the center of a width dimension of the electrode 3 in the direction orthogonal to the longitudinal direction of the electrode 3 and the center of a width dimension of the electrode 4 in the direction orthogonal to the longitudinal direction of the electrode 4. Further, when at least one of the electrodes 3 and 4 includes a plurality of electrodes (in a case where the electrodes 3 and 4 define a pair of electrodes, when 1.5 or more pairs of electrodes are present), the distance between the centers of the electrodes 3 and 4 refers to an average value of the distances between the centers of the electrodes 3 and 4 adjacent to each other among the 1.5 or more pairs of electrodes 3 and 4. In addition, the widths of the electrodes 3 and 4, that is, the dimensions of the electrodes 3 and 4 in a facing direction thereof are preferably within a range being equal to or more than about 150 nm and equal to or less than about 1000 nm, for example.

In this preferred embodiment, when a Z-cut piezoelectric layer is used, the direction orthogonal to the longitudinal direction of the electrodes 3 and 4 is a direction orthogonal to a polarization direction of the piezoelectric layer 2. This is not a case when a piezoelectric material having another cut angle is used as the piezoelectric layer 2. Here, the term “orthogonal” is not limited to strictly orthogonal but may be substantially orthogonal (like a case where the angle between the direction orthogonal to the longitudinal direction of the electrodes 3 and 4 and the polarization direction may be, for example, about 90°±10°).

A support 8 is laminated on the second main surface 2b side of the piezoelectric layer 2 with an insulating layer 7 interposed therebetween. Each of the insulating layer 7 and the support 8 has a frame shape, and the insulating layer 7 and the support 8 respectively have openings 7a and 8a as illustrated in FIG. 30. These form a cavity portion 9. The cavity portion 9 is provided in order not to interfere with vibration of an excitation region C (see FIG. 29) of the piezoelectric layer 2. Thus, the support 8 is laminated over the second main surface 2b with the insulating layer 7 interposed therebetween at a position not overlapping at least a portion where a pair of electrodes 3 and 4 are provided. Note that the insulating layer 7 does not need to be provided. Thus, the support 8 can be directly or indirectly laminated on or over the second main surface 2b of the piezoelectric layer 2.

The insulating layer 7 is made of, for example, silicon oxide. However, in addition to silicon oxide, an appropriate insulating material such as silicon oxynitride or alumina may be used. The support 8 is made of Si. A plane orientation of a surface of Si on the piezoelectric layer 2 side may be (100), (110), or (111). Preferably, Si having a high resistance, which is a resistivity being equal to or more than 4 kΩ, is desirable. Of course, the support 8 can also be formed by using an appropriate insulating material or a semiconductor material. Examples of the material of the support 8 include piezoelectric materials such as aluminum oxide, lithium tantalate, lithium niobate, and quartz crystal; various ceramics such as alumina, magnesia, sapphire, silicon nitride, aluminum nitride, silicon carbide, zirconia, cordierite, mullite, steatite, and forsterite; dielectrics such as diamond and glass; and semiconductors such as gallium nitride.

Each of the plurality of electrodes 3, the plurality of electrodes 4, the first busbar electrode 5, and the second busbar electrode 6 is made of an appropriate metal or alloy such as Al or an AlCu alloy. In the present preferred embodiment, the electrodes 3, the electrodes 4, the first busbar electrode 5, and the second busbar electrode 6 have a structure in which an Al film is laminated on a Ti film. Note that an adhesion layer other than the Ti film may be used.

At the time of driving, an AC voltage is applied between the plurality of electrodes 3 and the plurality of electrodes 4. More specifically, an AC voltage is applied between the first busbar electrode 5 and the second busbar electrode 6. This allows resonance characteristics utilizing a bulk wave in a thickness shear mode excited in the piezoelectric layer 2 to be obtained. Moreover, in the acoustic wave device 1, when a thickness of the piezoelectric layer 2 is defined as d and a distance between centers of any electrodes 3 and 4 adjacent to each other among the plurality of pairs of electrodes 3 and 4 is defined as p, d/p is less than or equal to about 0.5, for example. Thus, the bulk wave in the thickness shear mode is effectively excited, and excellent resonance characteristics can be obtained. More preferably, d/p is equal to or less than about 0.24, for example. In this case, more excellent resonance characteristics can be obtained. Note that in a case where at least one of the electrodes 3 and 4 includes a plurality of electrodes as in the present preferred embodiment, that is, in a case where 1.5 or more pairs of the electrodes 3 and 4 are present when the electrodes 3 and 4 are a pair of electrodes, the distance p between centers of the electrodes 3 and 4 adjacent to each other is an average distance of the distances between the centers of the electrodes 3 and 4 adjacent to each other.

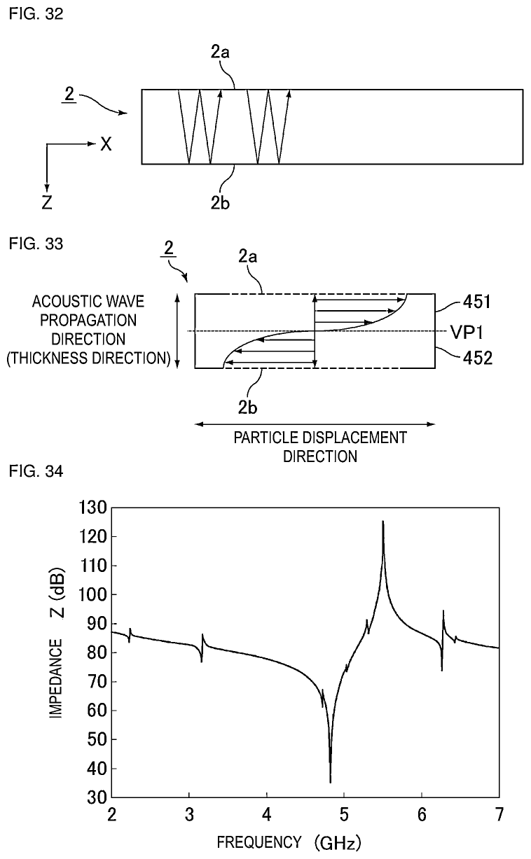

Since the acoustic wave device 1 according to the present preferred embodiment has the above-described configuration, even when the number of pairs of the electrodes 3 and 4 is reduced in order to miniaturize the acoustic wave device 1, a decrease in Q value is unlikely to occur. This is because the resonator does not require reflectors on both sides and has a small propagation loss. Moreover, the reason why the reflectors described above are not required is that the bulk wave in the thickness shear mode is used. A difference between the Lamb wave utilized in the conventional acoustic wave device and the bulk wave in the thickness shear mode will be described with reference to FIG. 31 and FIG. 32.

FIG. 31 is a schematic elevational cross-sectional view for describing the Lamb wave propagating through the piezoelectric film of the acoustic wave device. As illustrated in FIG. 31, in the acoustic wave device described in Japanese Unexamined Patent Application Publication No. 2012-257019 (Japanese Unexamined Patent Application Publication No. 2012-257019), a wave propagates in a piezoelectric film 201 as indicated by arrows. Here, in the piezoelectric film 201, a first main surface 201a and a second main surface 201b face each other, and a thickness direction connecting the first main surface 201a and the second main surface 201b is a Z direction. An X direction is a direction in which the electrode fingers of the IDT electrode are aligned. As illustrated in FIG. 31, regarding the Lamb wave, the wave propagates in the X direction as illustrated. The piezoelectric film 201 vibrates as a whole because the Lamb wave is a plate wave, but the wave propagates in the X direction. Thus, reflectors are disposed on both sides to obtain resonance characteristics. This generates a propagation loss of the wave. Because of this, the Q value decreases when miniaturization is attained, that is, when the number of pairs of electrode fingers is reduced.

On the other hand, FIG. 32 is a schematic elevational cross-sectional view for describing the bulk wave in the thickness shear mode propagating through the piezoelectric layer of the acoustic wave device. As illustrated in FIG. 32, in the acoustic wave device 1 according to the present preferred embodiment, since vibration displacement is generated in the thickness shear direction, the wave propagates almost in a direction connecting the first main surface 2a and the second main surface 2b of the piezoelectric layer 2, that is, in a Z direction, and resonates. That is, an X direction component of the wave is significantly smaller than a Z direction component. Since resonance characteristics are obtained by the propagation of the wave in the Z direction, reflectors are not required. Thus, a propagation loss is not generated when the wave propagates to the reflectors. Accordingly, even when the number of pairs of the electrodes 3 and 4 is reduced in order to attain miniaturization, the Q value is less likely to decrease.

FIG. 33 is a diagram illustrating an amplitude direction of the bulk wave in the thickness shear mode. As illustrated in FIG. 33, the amplitude direction of the bulk wave in the thickness shear mode is opposite between a first region 451 included in the excitation region C of the piezoelectric layer 2 and a second region 452 included in the excitation region C. FIG. 33 schematically illustrates the bulk wave when a voltage is applied between the electrode 3 and the electrode 4 such that the electrode 4 has a higher potential than that of the electrode 3. The first region 451 is a region of the excitation region C between the first main surface 2a and a virtual plane VP1 that is orthogonal to the thickness direction of the piezoelectric layer 2 and that divides the piezoelectric layer 2 into two portions. The second region 452 is a region of the excitation region C between the virtual plane VP1 and the second main surface 2b.

As described above, in the acoustic wave device 1, at least one pair of electrodes including the electrode 3 and the electrode 4 are disposed. However, since a wave is not propagated in the X direction, the number of pairs of electrodes including the electrodes 3 and 4 does not necessarily need to be plural. That is, it is sufficient that at least one pair of electrodes are provided.

For example, the electrode 3 is connected to a hot potential, and the electrode 4 is connected to a ground potential. However, the electrode 3 may be connected to the ground potential, and the electrode 4 may be connected to the hot potential. In the present preferred embodiment, as described above, at least one pair of electrodes are an electrode connected to the hot potential or an electrode connected to the ground potential, and a floating electrode is not provided.

FIG. 34 is a diagram illustrating an example of resonance characteristics of the acoustic wave device illustrated in FIG. 28. Note that examples of design parameters of the acoustic wave device 1 having the resonance characteristics are as follows.

Piezoelectric layer 2: LiNbO₃ with Euler angles (0°, 0°, the thickness=400 nm.

When viewed in the direction orthogonal to the longitudinal direction of the electrodes 3 and 4, the length of a region where the electrodes 3 and 4 overlap each other, that is, the excitation region C=40 μm, the number of pairs of electrodes including the electrodes 3 and 4=21, the distance between centers of the electrodes=3 μm, the width of the electrodes 3 and 4=500 nm, d/p=0.133.

Insulating layer 7: a silicon oxide film having a thickness of 1 μm.

Support 8: Si substrate.

Note that the length of the excitation region C is a dimension of the excitation region C along the longitudinal direction of the electrodes 3 and 4.

In the acoustic wave device 1, the distances between the electrodes included in the pair of electrodes including the electrodes 3 and 4 are set to be the same in all of the plurality of pairs. That is, the electrodes 3 and the electrodes 4 are disposed at equal pitches.

As is clear from FIG. 34, excellent resonance characteristics with a fractional bandwidth of about 12.5%, for example, can be obtained even though no reflector is provided.

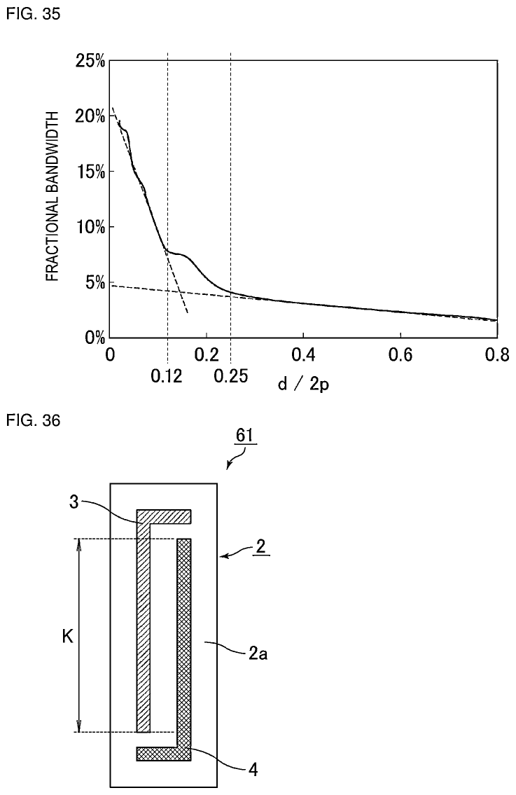

Incidentally, when the thickness of the piezoelectric layer 2 is defined as d and the distance between the centers of the electrodes 3 and 4 is defined as p, d/p is preferably equal to or less than about 0.5 and more preferably equal to or less than about 0.24, for example, in the present preferred embodiment as described above. This will be described with reference to FIG. 35.

A plurality of acoustic wave devices were obtained in a manner similar to that of the acoustic wave device having the resonance characteristics illustrated in FIG. 34, except that d/2p was changed. FIG. 35 is a diagram illustrating a relationship between d/2p when a distance between centers of electrodes adjacent to each other is defined as p, and a thickness of a piezoelectric layer is defined as d, and a fractional bandwidth of the acoustic wave device as a resonator.

As is clear from FIG. 35, when d/2p exceeds about 0.25, that is, when an expression of d/p>about 0.5 is satisfied, the fractional bandwidth is less than about 5% even when d/p is adjusted, for example. On the other hand, when an expression of d/2p≤about 0.25, that is, d/p≤about 0.5 is satisfied, the fractional bandwidth can be set to be equal to or more than about 5% by changing d/p within the range, for example. That is, a resonator having a high coupling coefficient can be formed. Moreover, when d/2p is equal to or less than about 0.12, that is, d/p is equal to or less than about 0.24, the fractional bandwidth can be increased to be equal to or more than about 7%, for example. In addition, when d/p is adjusted within this range, a resonator having a wider fractional bandwidth can be obtained, and a resonator having a higher coupling coefficient can be achieved. Thus, it is understood that by setting d/p to be equal to or less than about 0.5, for example, a resonator having a high coupling coefficient and using the bulk wave in the thickness shear mode can be formed.

Note that as described above, the at least one pair of electrodes may include only one pair, and in the case of the only one pair of electrodes, p, which has been described above, is the distance between the centers of the electrodes 3 and 4 adjacent to each other. Additionally, in the case of 1.5 or more pairs of electrodes, p may be set to the average distance of the distances between the centers of the electrodes 3 and 4 adjacent to each other.

As for the thickness d of the piezoelectric layer, when the piezoelectric layer 2 has variations in thickness, a value obtained by averaging the thicknesses may be used.

FIG. 36 is a plan view of another example of the acoustic wave device utilizing the bulk wave in the thickness shear mode.

In an acoustic wave device 61, a pair of electrodes including the electrodes 3 and 4 are provided on the first main surface 2a of piezoelectric layer 2. Note that K in FIG. 36 is an overlap width. As described above, in the acoustic wave device according to the present preferred embodiment, the number of pairs of electrodes may be one. Also in this case, when d/p, which has been described above, is equal to or less than about 0.5, for example, the bulk wave in the thickness shear mode can be effectively excited.

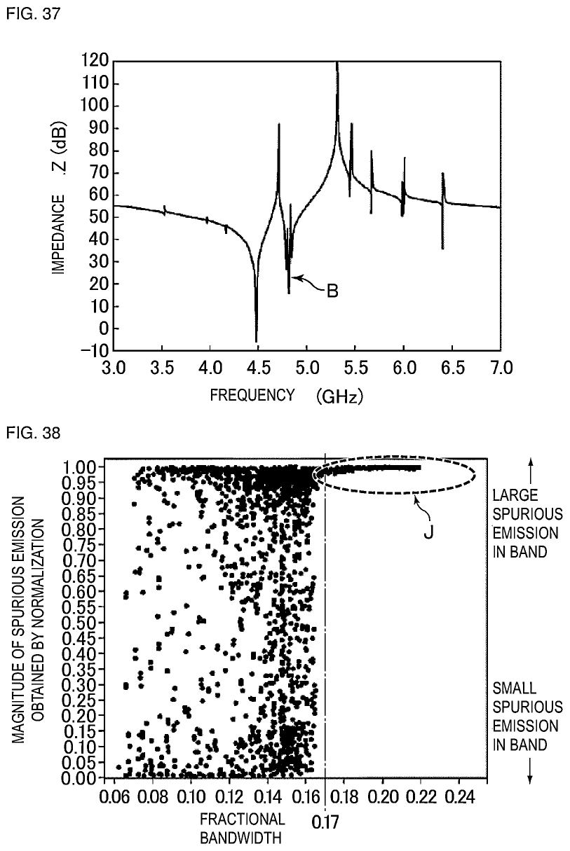

In the acoustic wave device according to the present preferred embodiment, it is preferable that a metallization ratio MR of the electrodes 3 and 4 adjacent to each other with respect to an excitation region, which is a region in which any electrodes 3 and 4 adjacent to each other overlap each other among the plurality of electrodes 3 and the plurality of electrodes 4 when viewed in the direction in which the electrodes 3 and 4 face each other, satisfy an expression of MR≤about 1.75(d/p)+0.075. In this case, spurious emissions can be effectively reduced. This will be described with reference to FIG. 37 and FIG. 38.

FIG. 37 is a reference diagram illustrating an example of resonance characteristics of the acoustic wave device illustrated in FIG. 28. A spurious emission indicated by an arrow B appears between a resonant frequency and an anti-resonant frequency. Note that d/p was set to about 0.08 and Euler angles of LiNbO₃ were set to (0°, 0°, 90°), for example. Further, the metallization ratio MR was set to about 0.35, for example.

The metallization ratio MR will be described with reference to FIG. 29. When attention is paid to a pair of electrodes 3 and 4 in an electrode structure in FIG. 29, it is assumed that only the pair of electrodes 3 and 4 are provided. In this case, a portion surrounded by a dashed-dotted line C is an excitation region. The excitation region is a region of the electrode 3 overlapping the electrode 4, a region of the electrode 4 overlapping the electrode 3, and a region where the electrode 3 and the electrode 4 overlap each other in a region between the electrode 3 and the electrode 4 when the electrode 3 and the electrode 4 are viewed in the direction orthogonal to the longitudinal direction of the electrodes 3 and 4, that is, in the facing direction. Then, a ratio of an area of the electrodes 3 and 4 in the excitation region C with respect to an area of the excitation region is the metallization ratio MR. That is, the metallization ratio MR is a ratio of an area of the metallization portion with respect to an area of the excitation region.

Note that when a plurality of pairs of electrodes are provided, a ratio of areas of metallization portions included in all excitation regions with respect to a total of areas of all the excitation regions may be defined as MR.

FIG. 38 is a diagram illustrating relationships between fractional bandwidths and phase rotation amounts of impedances of spurious emissions normalized by 180 degrees as magnitudes of the spurious emissions when a large number of acoustic wave resonators are configured according to the present preferred embodiment. Note that the fractional bandwidth was adjusted by variously changing the film thickness of the piezoelectric layer and the dimensions of the electrodes. In addition, FIG. 38 illustrates a result in a case of using the piezoelectric layer made of Z-cut LiNbO₃, but similar tendencies are seen also in cases of using piezoelectric layers having other cut angles.

In a region surrounded by an ellipse J in FIG. 38, spurious emissions are about 1.0, for example, which is large. As is clear from FIG. 38, when the fractional bandwidth exceeds about 0.17, that is, exceeds about 17%, for example, a large spurious emission having a spurious level equal to or more than 1 appears in the pass band even when parameters of the fractional bandwidth are changed. That is, as in the resonance characteristics illustrated in FIG. 37, the large spurious emission indicated by the arrow B appears in the band. Thus, the fractional bandwidth is preferably equal to or less than about 17%, for example. In this case, spurious emissions can be reduced by adjusting the film thickness of the piezoelectric layer 2, the dimensions of the electrodes 3 and 4, and the like.

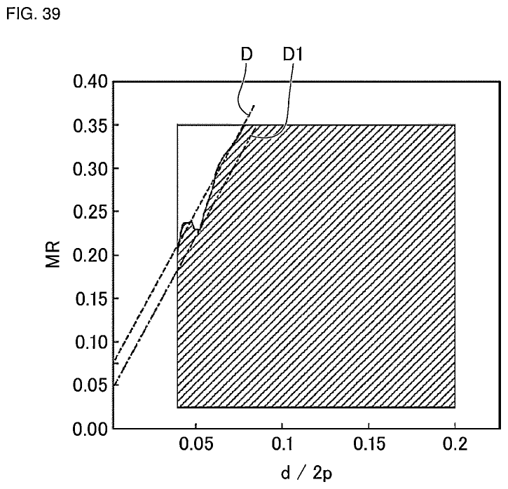

FIG. 39 is a diagram illustrating relationships among d/2p, metallization ratios MR, and fractional bandwidths. In the above-described acoustic wave device, various acoustic wave devices having different values of d/2p and different values of MR were formed, and the fractional bandwidths were measured.

A hatched portion on the right side of a broken line D in FIG. 39 is a region where the fractional bandwidth is equal to or less than about 17%, for example. A boundary between the hatched region and the non-hatched region is represented by an equation of MR=about 3.5(d/2p)+0.075, for example. That is, an equation of MR=about 1.75(d/p)+0.075 is satisfied. Thus, an expression of MR≤about 1.75(d/p)+0.075 is preferably satisfied, for example. In this case, the fractional bandwidth is likely to be equal to or less than about 17%, for example. The region on the right side of an equation of MR=about 3.5(d/2p)+0.05 indicated by a dashed-dotted line D1 in FIG. 39 is more preferable, for example. That is, when an expression of MR≤about 1.75(d/p)+0.05 is satisfied, the fractional bandwidth can be reliably set to be equal to or less than about 17%, for example.

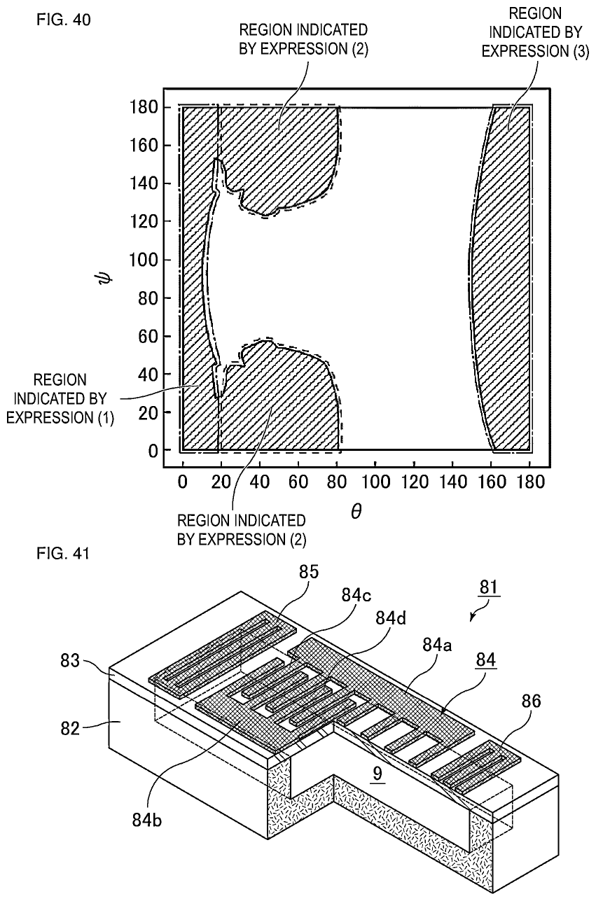

FIG. 40 is a diagram illustrating a map of fractional bandwidths with respect to Euler angles (0°, θ, ψ) of LiNbO₃ when d/p is made as close to 0 as possible.

A hatched portion in FIG. 40 is a region in which the fractional bandwidth at least equal to or more than about 5%, for example, is obtained. When a range of the region is approximated, the range is represented by the following Expression (1), Expression (2), and Expression (3).

(0°±10°,0° to 20°,freely selected ψ) Expression (1)

(0°±10°,20° to 80°,0° to 60°(1−(θ−50)²/900)^{1/2}) or (0°±10°,20° to 80°,[180°−60°(1−(θ−50)²/900)^{1/2}] to 180°) Expression (2)

(0°±10°,[180°−30°(1−(ψ−90)²/8100)^{1/2}] to 180°, freely selected ψ) Expression (3)

Thus, in the case of the range of Euler angles of the above Expression (1), Expression (2), or Expression (3), the fractional bandwidth can be sufficiently widened, which is preferable.

FIG. 41 is a partially cutout perspective view for describing an example of the acoustic wave device utilizing the Lamb wave.

An acoustic wave device 81 includes a support substrate 82. The support substrate 82 is provided with a recessed portion that is open to an upper surface thereof. A piezoelectric layer 83 is laminated on the support substrate 82. Thus, the cavity portion 9 is formed. An IDT electrode 84 is provided on the piezoelectric layer 83 above the cavity portion 9. Reflectors 85 and 86 are provided on both sides of the IDT electrode 84 in an acoustic wave propagation direction. In FIG. 41, outer peripheral edges of the cavity portion 9 are indicated by broken lines. Here, the IDT electrode 84 includes a first busbar electrodes 84a, a second busbar electrode 84b, a plurality of electrodes 84c as first electrode fingers, and a plurality of electrodes 84d as second electrode fingers. The plurality of electrodes 84c are connected to the first busbar electrode 84a. The plurality of electrodes 84d are connected to the second busbar electrode 84b. The plurality of electrodes 84c and the plurality of electrodes 84d are interdigitated with each other.

In the acoustic wave device 81, a Lamb wave as a plate wave is excited by applying an AC electric field to the IDT electrode 84 over the cavity portion 9. Additionally, since the reflectors 85 and 86 are provided on the both sides, resonance characteristics using the Lamb wave can be obtained.

As described above, an acoustic wave device according to a preferred embodiment of the present invention may utilize a plate wave such as a Lamb wave.

Alternatively, an acoustic wave device according to a preferred embodiment of the present invention may utilize a bulk wave. That is, an acoustic wave device according to a preferred embodiment of the present invention can also be applied to a bulk acoustic wave (BAW) element. In this case, the functional electrodes are an upper electrode and a lower electrode.

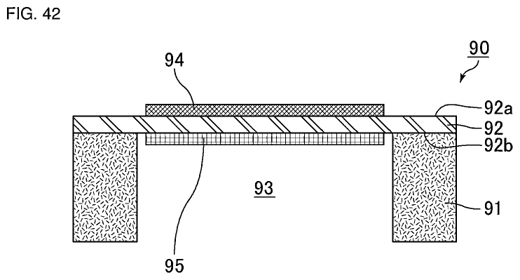

FIG. 42 is a cross-sectional view schematically illustrating an example of the acoustic wave device utilizing the bulk wave.

An acoustic wave device 90 includes a support substrate 91. A cavity portion 93 is provided so as to penetrate through the support substrate 91. A piezoelectric layer 92 is laminated on the support substrate 91. An upper electrode 94 is provided on a first main surface 92a of the piezoelectric layer 92, and a lower electrode 95 is provided on a second main surface 92b of the piezoelectric layer 92.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first main surface and a second main surface that are opposed to each other;
a plurality of electrodes located on at least one main surface of the first main surface and the second main surface of the piezoelectric layer; and
a support substrate located on a side of the second main surface of the piezoelectric layer; wherein
the plurality of electrodes include at least one pair of functional electrodes and a wiring electrode connected to each of the at least one pair of functional electrodes;
the at least one pair of functional electrodes include a first functional electrode connected to a signal wiring line and a second functional electrode paired with the first functional electrode;
the wiring electrode includes one or more first wiring electrodes connected to each of the first functional electrode and the second functional electrode;
a cavity portion is located between the support substrate and the piezoelectric layer; and
an entirety of the first functional electrode and an entirety of a first wiring electrode connected to the first functional electrode among the one or more first wiring electrodes are located on at least one of the first main surface and the second main surface of the piezoelectric layer in an overlapping manner with the cavity portion when viewed from a laminating direction of the support substrate and the piezoelectric layer.

2. The acoustic wave device according to claim 1, wherein an entirety of a second functional electrode connected to a signal wiring line among the second functional electrodes and an entirety of a first wiring electrode connected to the second functional electrode among the one or more first wiring electrodes are located on at least one of the first main surface and the second main surface of the piezoelectric layer in an overlapping manner with the cavity portion when viewed from the laminating direction of the support substrate and the piezoelectric layer.

3. The acoustic wave device according to claim 1, wherein no electrode is provided at a position not overlapping the cavity portion on the first main surface or the second main surface of the piezoelectric layer when viewed in the laminating direction of the support substrate and the piezoelectric layer.

4. The acoustic wave device according to claim 1, wherein
the first functional electrode, the second functional electrode, and the one or more first wiring electrodes are located on the first main surface of the piezoelectric layer; and
the acoustic wave device further comprises:
a first cover portion spaced from the first main surface of the piezoelectric layer in an overlapping manner with the first functional electrode, the second functional electrode, and the one or more first wiring electrodes when viewed from the laminating direction of the support substrate and the piezoelectric layer;
a first support portion located between the first cover portion and the piezoelectric layer or the support substrate;
a second wiring electrode located on at least one first wiring electrode among the one or more first wiring electrodes, the second wiring electrode being connected to the at least one first wiring electrode; and
a third wiring electrode located on a main surface of the first cover portion on a side of the piezoelectric layer, the third wiring electrode being connected to the second wiring electrode.

5. The acoustic wave device according to claim 4, further comprising:
a terminal electrode penetrating through the first cover portion, the terminal electrode being electrically connected to the third wiring electrode; and
a pad electrode located on or over a main surface of the first cover portion on a side opposite to the piezoelectric layer, the pad electrode being connected to the terminal electrode.

6. The acoustic wave device according to claim 4, wherein
the cavity portion penetrates through the support substrate; and
the acoustic wave device further comprises:
a second cover portion located on a side opposite to the piezoelectric layer over the support substrate, the second cover portion closing the cavity portion; and
a second support portion located between the second cover portion and the support substrate.

7. The acoustic wave device according to claim 1, wherein the first functional electrode includes:
one or more first electrodes; and
a first busbar electrode to which the one or more first electrodes are connected;
the second functional electrode includes:
one or more second electrodes; and
a second busbar electrode to which the one or more second electrodes are connected; and
the one or more first electrodes, the first busbar electrode, the one or more second electrodes, and the second busbar electrode are located on the first main surface of the piezoelectric layer.

8. The acoustic wave device according to claim 7, wherein when a distance between centers of a first electrode and a second electrode that are adjacent to each other among the one or more first electrodes and the one or more second electrodes is defined as p, a thickness of the piezoelectric layer is equal to or less than 2p.

9. The acoustic wave device according to claim 1, wherein the piezoelectric layer is made of lithium niobate or lithium tantalate.

10. The acoustic wave device according to claim 9, wherein the acoustic wave device is structured to generate a bulk wave in a thickness shear mode.

11. The acoustic wave device according to claim 7, wherein an expression of d/p≤about 0.5 is satisfied when a thickness of the piezoelectric layer is defined as d, and a distance between centers of a first electrode and a second electrode that are adjacent to each other among the one or more first electrodes and the one or more second electrodes is defined as p.

12. The acoustic wave device according to claim 11, wherein an expression of d/p≤about 0.24 is satisfied.

13. The acoustic wave device according to claim 7, wherein an expression of MR≤about 1.75(d/p)+0.075 is satisfied when a metallization ratio is defined as MR, the metallization ratio being a ratio of an area of a first electrode and a second electrode that are adjacent to each other with respect to an area of an excitation region where the first electrode and the second electrode that are adjacent to each other overlap each other when viewed in a direction in which the first electrode and the second electrode that are adjacent to each other face each other, among the one or more first electrodes and the one or more second electrodes, a thickness of the piezoelectric layer is defined as d, and a distance between centers of the first electrode and the second electrode that are adjacent to each other is defined as p.

14. The acoustic wave device according to claim 13, wherein an expression of MR≤about 1.75(d/p)+0.05 is satisfied.

15. The acoustic wave device according to claim 1, wherein one of the first functional electrode and the second functional electrode is an upper electrode located on the first main surface of the piezoelectric layer, and another of the first functional electrode and the second functional electrode is a lower electrode located on the second main surface of the piezoelectric layer.

16. The acoustic wave device according to claim 9, wherein Euler angles (φ, θ, ψ) of the lithium niobate or the lithium tantalate are within a range of the following Expression (1), Expression (2), or Expression (3):
(0°±10°,0° to 20°,freely selected ψ) Expression (1);
(0°±10°,20° to 80°,0° to 60°(1−(θ−50)²/900)^{1/2}) or (0°±10°,20° to 80°,[180°−60°(1−(θ−50)²/900)^{1/2}] to 180°) Expression (2); and
(0°±10°,[180°−30°(1−(ψ−90)²/8100)^{1/2}] to 180°, freely selected ψ) Expression (3).

17. The acoustic wave device according to claim 1, wherein the acoustic wave device is structured to generate a plate wave.

18. The acoustic wave device according to claim 1, further comprising reflectors provided on both ends of the at least one pair of functional electrodes.

19. A manufacturing method of an acoustic wave device comprising:
preparing an intermediate including a piezoelectric layer including a first main surface and a second main surface that are opposed to each other, a plurality of electrodes located on at least one of the first main surface and the second main surface of the piezoelectric layer, and a support substrate laminated on a side of the second main surface of the piezoelectric layer, the plurality of electrodes including at least one pair of functional electrodes and a wiring electrode connected to each of the at least one pair of functional electrodes, the at least one pair of functional electrodes including a first functional electrode connected to a signal wiring line and a second functional electrode paired with the first functional electrode, the wiring electrode including one or more first wiring electrodes connected to each of the first functional electrode and the second functional electrode;
after the preparing the intermediate, first cover portion joining of disposing a first cover portion at an interval from the first main surface of the piezoelectric layer in an overlapping manner with the first functional electrode, the second functional electrode, and the one or more first wiring electrodes in a view from a laminating direction of the support substrate and the piezoelectric layer, disposing a first support portion between the first cover portion and the piezoelectric layer or the support substrate, and then, joining the first cover portion with the piezoelectric layer or the support substrate;
forming a terminal hole penetrating through the first cover portion;
forming a terminal electrode in the terminal hole;
forming a pad electrode connected to the terminal electrode on or over a main surface of the first cover portion on an opposite side to the piezoelectric layer;
forming a cavity portion penetrating through the support substrate; and
second cover portion joining of disposing a second cover portion covering the cavity portion on an opposite side to the piezoelectric layer over the support substrate, disposing a second support portion between the second cover portion and the support substrate, and then, joining the second cover portion with the support substrate.

20. The method according to claim 19, wherein
the intermediate includes a piezoelectric layer including a plurality of singulation regions partitioned when viewed from a direction in which the first main surface and the second main surface are opposed to each other, at least one pair of electrodes provided in each of the plurality of singulation regions, and a support substrate laminated on a side of the second main surface of the piezoelectric layer in a manner straddling over a boundary between the singulation regions; and
the method further comprises cutting the piezoelectric layer, the support substrate, the first cover portion, and the second cover portion along the boundary between the singulation regions.
